(19) United States
(12) Patent Application Publication
(10) Pub. No.: US 2026/0079219 A1
(43) Pub. Date: Mar. 19, 2026

(54) Measuring Device for Measuring a Magnetic Field Strength in an Environment of a Magnetic Resonance Device

(71) Applicant: Siemens Healthineers AG, Forchheim (DE)

(72) Inventors: Johann Sukkau, Herzogenaurach (DE); Andrew Dewdney, Neunkirchen am Brand (DE); Hannes Hotzmann, Fürth (DE)

(73) Assignee: Siemens Healthineers AG, Forchheim (DE)

(21) Appl. No.: 19/326,925

(22) Filed: Sep. 12, 2025

(30) Foreign Application Priority Data
Sep. 13, 2024 (DE) 10 2024 208 750.5

(51) Int. Cl. G01R 33/24; G01R 33/00

(52) U.S. Cl. CPC G01R 33/24; G01R 33/0005; G01R 33/0094

(57) ABSTRACT

The disclosure is directed to a measuring device for acquiring a magnetic field strength in the environment of a magnetic resonance device. The measuring device may include two or more magnetic field sensors. The measuring device may include a sensor rod on which the two or more magnetic field sensors are arranged and distributed.

### CROSS REFERENCE TO RELATED APPLICATIONS

This patent application claims priority to German Patent Application No. 102024208750.5, filed Sep. 13, 2024, which is incorporated herein by reference in its entirety.

### BACKGROUND

The present disclosure relates to a measuring device for acquiring a magnetic field strength in an environment of a magnetic resonance device, wherein the measuring device may comprise two or more magnetic field sensors. The present disclosure further relates to a method for providing location-dependent magnetic field strength data for an environment of a magnetic resonance device.

Mobile magnetic resonance devices are used to offer magnetic resonance examinations to patients living in a region with poor health infrastructure. Such mobile magnetic resonance devices are arranged in a transport container and can be moved to different locations by truck. However, as a width of an internal space of the transport container is almost completely taken up by a scanner unit of the magnetic resonance device, it is important to know a distribution of the magnetic field outside the transport container, particularly a strength of the magnetic field, in order to protect patients against a risk from the magnetic field.

A 5 gauss line, which is visibly marked around the transport container, is thereby significant. The 5 gauss line is the safety line drawn around the perimeter of a main magnet of the scanner unit of the magnetic resonance device and specifies the distance at which the magnetic stray field of the magnet unit corresponds to 5 gauss (0.5 mT). A value of 5 gauss and below is considered the safe level of static magnetic field exposure for the public. For example, an area outside the 5 gauss line is non-critical for the functioning of pacemakers, or the functioning of insulin pumps, or of implants affected by electromagnetism.

The magnetic field strength outside a transport container has been acquired manually to date. A user acquires the data manually for this purpose at each measuring point by means of a magnetic field measuring device. Measurements are generally taken here with a grid density of 20×20 cm or 10×10 cm up to a height of approx. 2 m. With a transport container approx. 7 m long and 2.6 m wide, this is an extremely time-consuming process.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 shows a measuring device according to an exemplary embodiment of the disclosure in a measurement state.

FIG. 2 shows the measuring device in a storage state, according to an exemplary embodiment.

FIG. 3 is a top view of the measuring device in the environment of a magnetic resonance device, according to an exemplary embodiment.

FIG. 4 shows the measuring device on an outer wall of a transport container in a measurement state, according to an exemplary embodiment.

FIG. 5 is a flow chart of a method for providing location-dependent magnetic field strength data for an environment of a magnetic resonance device, according to an exemplary embodiment.

The exemplary embodiments of the present disclosure will be described with reference to the accompanying drawings. Elements, features and components that are identical, functionally identical and have the same effect are—insofar as is not stated otherwise—respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the present disclosure is to facilitate easy and quick acquisition of a magnetic field strength in an environment of a magnetic resonance device.

The present disclosure is based on a measuring device for acquiring magnetic field strength in an environment of a magnetic resonance device, wherein the measuring device may comprise two or more magnetic field sensors. It is proposed according to the disclosure that the measuring device may comprise a sensor rod, on which the two or more magnetic field sensors are arranged distributed.

The magnetic resonance device may comprise a medical and/or diagnostic magnetic resonance device, designed and/or configured to acquire medical and/or diagnostic image data, in particular medical and/or diagnostic magnetic resonance image data, of a patient. The magnetic resonance device may comprise the scanner unit for this purpose. The scanner unit may comprise a magnet unit for acquiring the medical and/or diagnostic image data. Advantageously, the scanner unit, particularly the magnet unit, hereby may comprise a base magnet, a gradient coil unit, and a radio-frequency antenna unit. The base magnet may be configured to generate a homogeneous base magnetic field with a defined magnetic field strength, for example, with a magnetic field strength of 3 T or 1.5 T. In particular, the base magnet may be configured to generate a strong and constant base magnetic field.

The magnetic resonance device may be embodied as a mobile magnetic resonance device. The magnetic resonance device is positioned in a transport container for this purpose, so that the magnetic resonance device can easily be moved from one location to another by means of a truck. Within the transport container, the magnetic resonance device is fully functional and operational for performing magnetic resonance examinations on patients. The environment of the magnetic resonance device may be outside the transport container.

The sensor rod may comprise a rod, on which two or more magnetic field sensors are arranged and/or fixed. The two or more magnetic field sensors are arranged and/or fixed distributed, particularly spaced apart, on the sensor rod. In particular, the two or more magnetic field sensors are arranged and/or fixed on the sensor rod distributed in the longitudinal direction of the sensor rod, particularly spaced apart. The two or more magnetic field sensors may comprise 3D magnetic field sensors, which acquire a magnetic field strength in all three spatial directions. The sensor rod may be arranged vertically to acquire the magnetic field strength. The sensor rod can thereby be arranged vertically on the outer wall of the transport container. The sensor rod can thereby abut the outer wall of the transport container or be arranged at a minimal distance to the outer wall of the transport container.

The disclosure has the advantage that a magnetic field strength can be acquired simultaneously at multiple measuring points, particularly at arrangement points and/or fixing points of the two or more magnetic field sensors on the sensor rod. This facilitates easy and quick acquisition of a magnetic field strength in an environment of a magnetic resonance device for a user, as the measuring points no longer need to be measured individually one after the other. This can reduce the time involved in installing and/or providing a mobile magnetic resonance device at a place of use, thereby increasing the cost-effectiveness of a mobile magnetic resonance device.

In one advantageous development of the measuring device according to the disclosure, it can be provided that the two or more magnetic field sensors are arranged on the sensor rod in such a way that two adjacent magnetic field sensors are always an equal distance apart. The distance between the two adjacent magnetic field sensors may be set to not exceed 20 cm. The distance can be exactly 20 cm or also exactly 15 cm or also exactly 10 cm. The two or more magnetic field sensors may be arranged with this defined distance between them along the entire sensor rod, particularly in the longitudinal direction of the sensor rod. Advantageously, the sensor rod may comprise a length of at least 1.5 m. The sensor rod may comprise a length of at least 1.6 m. The sensor rod may comprise a length of at least 1.7 m. The sensor rod may comprise a length of at least 1.8 m. The sensor rod may comprise a length of at least 1.9 m. In an exemplary embodiment, the sensor rod may comprise a length of at least 2.0 m. Accordingly, with a maximum distance between adjacent magnetic field sensors of 20 cm, the measuring device may comprise at least 10 magnetic field sensors or, with a smaller distance between two adjacent magnetic field sensors, more than 10 magnetic field sensors.

The embodiment of the disclosure has the advantage that the magnetic field strength can be acquired simultaneously for all measuring points in the vertical direction, particularly parallel to a direction of a weight force, at a position, particularly a measuring position, along the perimeter of the transport container. The work involved in acquiring magnetic field strength data can be reduced considerably as a result.

In one advantageous development of the measuring device according to the disclosure, it can be provided that the measuring device may comprise a travel unit, wherein the travel unit may comprise a platform, wherein the sensor rod is arranged on the platform. In addition to the platform, the travel unit also may comprise at least one wheel and/or one roller for moving the measuring device in the space. The platform can be used to achieve advantageous stability when positioning the sensor rod. Furthermore, the travel unit also allows for easy positioning of the measuring device in the space.

In one advantageous development of the measuring device according to the disclosure, it can be provided that the sensor rod includes a longitudinal extension, which is aligned orthogonally to a surface of the platform. The surface of the platform may be aligned horizontally for use of the measuring device according to the disclosure. Accordingly, the sensor rod is aligned vertically for use of the measuring device according to the disclosure. The sensor rod can thus be positioned easily in the environment of the magnetic resonance device. In particular, the measuring device only has to be positioned at a measuring position and the sensor rod is operational for acquiring magnetic field strength data. The magnetic field strength in an environment of a magnetic resonance device can also be acquired easily and quickly by repositioning the platform on an outer wall of the transport container.

In one advantageous development of the measuring device according to the disclosure, it can be provided that the travel unit may comprise at least two wheels. A user can thus easily and conveniently change the position of the measuring device for acquiring the magnetic field strength at other measuring positions, particularly at defined measuring positions and/or measuring points on a perimeter of a base area of the transport container.

The travel unit may comprise three wheels. Particularly advantageously, however, the travel unit may comprise four wheels. In addition to easily changing the position of the measuring device, it is also possible to achieve a stable arrangement and/or positioning at a measuring position, particularly at a defined measuring position on the perimeter of the transport container.

In one advantageous development of the measuring device according to the disclosure, it can be provided that at least one of the wheels may comprise just one rotational axis and at least one of the wheels may comprise two rotational axes. In the case of wheels that comprise just one rotational axis, the rotational axis may include a fixed position with respect to the platform and does not change its alignment with respect to the platform when the measuring device moves. The respective wheel rotates about this rotational axis to move the measuring device. This rotational axis may be perpendicular to an idealized circular area, wherein the circular area is encompassed by an outer surface of the wheel, which may comprise a rolling surface of the wheel.

At least one of the wheels may comprise two rotational axes with a first rotational axis and a second rotational axis. The first rotational axis is identical to the rotational axis of the wheels with just one rotational axis. The second rotational axis may be aligned perpendicular to the first rotational axis. When the at least one wheel rotates about the second rotational axis, it is possible to determine the measuring device's direction of movement. The second rotational axis may be aligned parallel to a vertical axis and/or to a direction of the weight force. If, for example, the travel unit may comprise three or four wheels, the rear wheels, particularly the wheels arranged on a side of the measuring device facing the user, may comprise just one single rotational axis, and the front wheels, particularly the wheels arranged on a side of the measuring device facing away from the user, may comprise two rotational axes.

Embodiments of the disclosure facilitate easy positioning of the measuring device at different measuring positions on an outer wall of the transport container for acquiring the strength of the magnetic field.

In one advantageous development of the measuring device according to the disclosure, it can be provided that the travel unit may include a drive unit. The drive unit may comprise a motor unit for generating a drive moment to make the measuring device move, particularly to make it run. This enables a user to position the measuring device conveniently and effortlessly at a measuring position. Moreover, the measuring device can thus also be positioned at a measuring position at least partially automatically.

In one advantageous development of the measuring device according to the disclosure, it can be provided that the sensor rod may comprise at least one folding unit. The folding unit can thereby comprise a hinge element, which may be configured to fold at least one sensor rod element of the sensor rod in or out again with respect to the platform and/or with respect to another sensor rod element. In addition, the folding unit can comprise other folding mechanisms deemed useful by the person skilled in the art. Furthermore, the folding unit can comprise at least one locking element and/or fixing element, which may be configured to fix and/or lock the at least one sensor rod element, particularly to fix and/or lock it removably and/or reversibly, in a measurement arrangement and/or in a measurement state, particularly in a folded-out position, with respect to the platform and/or with respect to another sensor rod element. Moreover, the locking element and/or fixing element can also be designed to fix and/or lock the at least one sensor rod element, particularly to fix and/or lock it removably and/or reversibly, in a folded-in position, particularly in a storage arrangement and/or a storage state, with respect to the platform and/or with respect to another sensor rod element.

The sensor rod may include at least two sensor rod elements, wherein a first folding unit of the sensor rod is arranged between the two sensor rod elements. The two sensor rod elements may be equal in length. In a folded-in position of the two sensor rod elements, particularly in a storage arrangement and/or a storage state, a longitudinal side of one element always abuts a longitudinal side of the other. A second folding unit of the sensor rod may be arranged between a lower sensor rod element and the platform. A longitudinal side of the lower sensor rod element faces the platform in a folded-in position, particularly in a storage arrangement and/or a storage state. The lower sensor rod element can also rest on the platform with this longitudinal side.

In the measurement arrangement and/or the measurement state of the measuring device, the measuring device is always operational for acquiring a magnetic field strength. The sensor rod is thereby in a folded-out state and/or a folded-out arrangement and all sensor elements are operational for acquiring a magnetic field strength. If, by contrast, the measuring device is in the storage arrangement and/or in the storage state, the measuring device is inactive and a magnetic field strength cannot be acquired. In particular, the sensor rod is arranged folded in on the platform in the storage arrangement and/or in the storage state.

The measuring device can thus be arranged in a particularly space-saving manner for storage of the measuring device, particularly when the measuring device is not in operation. Additionally, a user can convert the measuring device in an easy and time-saving manner from the measurement arrangement and/or the measurement state to the storage arrangement and/or the storage state and vice versa by means of the at least one folding unit.

In one advantageous development of the measuring device according to the disclosure, it can be provided that the measuring device may include a position detection unit, which may be configured to detect a change in the measuring device's position, wherein the position detection unit may comprise a route sensor. The route sensor may be configured to detect a distance and/or path length traveled by means of the measuring device. A change in position with respect to a reference position may be detected by means of the route sensor. The reference position can thereby comprise a defined position on a perimeter of a base area of the transport container or also a position of a previous measuring point. For example, the defined point on the perimeter of the base area of the transport container can comprise a corner point, at which two wall surfaces meet, or an opening and/or door of the transport container. Furthermore, the reference position can comprise other positions in the environment of the magnetic resonance device deemed useful by the person skilled in the art. A user can thus be assisted advantageously with positioning the measuring device at a measuring point. Additionally, the position information acquired by the route sensor can advantageously be used to determine location-dependent magnetic field strength data.

In one advantageous development of the measuring device according to the disclosure, it can be provided that the route sensor is arranged coaxially to a rotational axis on a wheel of the travel unit. A distance traveled by the measuring device, particularly a wheel of the travel unit, can thus be acquired directly when there is a change in position. The route sensor can, for example, comprise an angle sensor and/or rotary encoder, which determine a traveled distance on the basis of a rotation and/or change in angle of the wheel about the rotational axis. The route sensor may be arranged coaxially to a rotational axis, about which the wheel turns to roll the wheel and/or move the measuring device. A particularly simple arrangement of the route sensor can thereby be advantageously achieved if the route sensor is arranged coaxially to the rotational axis on a wheel of the measuring device with just one rotational axis.

In one advantageous development of the measuring device according to the disclosure, it can be provided that the position detection unit may comprise a direction sensor, wherein the direction sensor is arranged on the wheel of the travel unit with two rotational axes. The direction sensor may be arranged coaxially here to a rotational axis of the wheel, wherein the wheel rotates about the rotational axis in the event of a change in direction while the measuring device is moving. The direction sensor can, for example, comprise an angle sensor and/or rotary encoder, which determine a change in direction of the measuring device on the basis of a rotation and/or change in angle of the wheel. A change in the measuring device's position can thus be determined advantageously, and a user can be assisted advantageously with positioning the measuring device at a measuring point. In particular, coupled with the route sensor, the position can be determined easily and quickly for acquiring the magnetic field strength at different measuring positions and/or measuring points on a perimeter of a base area of the transport container. Moreover, the position information acquired by the route sensor and the direction sensor can advantageously be used to determine location-dependent magnetic field strength data.

In one advantageous development of the measuring device according to the disclosure, it can be provided that the position detection unit may comprise a distance sensor, which may be configured to determine a distance to a reference surface. The reference surface may comprise a wall surface, for example, an outer surface of the transport container. The distance sensor can comprise one or more time-of-flight (TOF) sensors. Alternatively, or additionally, the distance sensor can also comprise one or more 2D cameras. Alternatively, or additionally, the distance sensor can also comprise one or more 3D cameras. Alternatively, or additionally, the distance sensor can also comprise one or more light detection and ranging (LIDAR) sensors. A user can thus be assisted advantageously with correct positioning of the measuring device on the outer surface of the transport container. In particular, the measuring device can thereby be positioned at a correct distance to the wall surface, particularly to the outer surface of the transport container, for acquiring the magnetic field strength.

In one advantageous development of the measuring device according to the disclosure, it can be provided that the distance sensor on the sensor rod is arranged on an end area of the sensor rod facing away from the platform. In particular, the distance sensor is arranged here in a measurement arrangement and/or a measurement state of the measuring device, particularly of the sensor rod, on an end area of the sensor rod facing away from the platform. The distance sensor is advantageously arranged in an area as a result, in which an unwanted incorrect positioning, for example, if a substrate on which the measuring device is positioned is uneven or has an incline, has a particularly severe effect due to the length of the sensor rod, so that an incorrect positioning of the individual magnetic field sensors can advantageously be detected.

In one advantageous development of the measuring device according to the disclosure, it can be provided that the measuring device may include a controller, which may be configured to evaluate sensor data from the two or more magnetic field sensors and/or from sensors of the position detection unit. The sensors of the position detection unit can thereby comprise the route sensor and/or the direction sensor and/or the distance sensor. The controller may be designed to evaluate all sensors present in the measuring device. The controller may include an evaluation unit for evaluating the sensor data from the individual sensors of the measuring device. The controller, particularly the evaluation unit, is connected to the individual sensors, particularly the magnetic field sensors and the sensors of the position detection unit, for evaluating the sensor data for a data transmission. When evaluating the sensor data, the controller, particularly the evaluation unit, may be configured to link together the data from the individual sensors of the measuring device, particularly all sensors of the measuring device, so that location-dependent data for the magnetic field strength can be determined and provided by the controller, particularly the evaluation unit. The acquired measured values for magnetic field strength can thereby comprise both location information with respect to the measuring points on the horizontal plane, for example, through data from the route sensor and/or through data from the direction sensor, and location information in the vertical direction, for example, on the basis of a positioning of the magnetic field sensors at different positions along the sensor rod. The positions at which the individual magnetic field sensors are arranged on the sensor rod may be recorded and/or saved in the controller, for example, in a memory unit of the controller, for the individual magnetic field sensors.

A user can thus be provided particularly quickly with location-dependent magnetic field strength data in the environment of the magnetic resonance device, particularly on an outer wall of the transport container. Additionally, the controller, particularly the evaluation unit, can also create a location-dependent magnetic field strength map of the environment of the magnetic resonance device, particularly on an outer wall of the transport container, and provide this to a user.

The controller according to the disclosure, particularly the evaluation unit, may comprise at least one calculation module and/or a processor. The controller, particularly the evaluation unit, is thus designed in particular to execute computer-readable instructions. In particular, the controller, particularly the evaluation unit, may comprise a memory unit, wherein computer-readable information is stored on the memory unit, wherein the controller, particularly the evaluation unit, may be configured to load the computer-readable information from the memory unit and to execute the computer-readable information. The controller, particularly the evaluation unit, is thus advantageously designed to evaluate sensor data from the two or more magnetic field sensors and/or from sensors of the position detection unit and to determine location-dependent magnetic field strength data.

The components of the controller, particularly the evaluation unit, can for the most part be designed in the form of software components. Essentially, however, these components can also be partially implemented in the form of software-supported hardware components, for example, FPGAs, particularly if especially fast calculations are involved. The required interfaces can also be embodied as software interfaces, for example, if it is only a matter of transferring data from other software components. However, they can also be embodied as hardware-based interfaces that are controlled by suitable software. Of course, it is also conceivable for several of the stated components to be implemented in the form of an individual software component or software-supported hardware component.

In one advantageous development of the measuring device according to the disclosure, it can be provided that the controller may be configured to control at least partially automatic positioning of the measuring device. In particular, the controller may be configured to control the drive unit of the travel unit here. For automatic positioning of the measuring device at a measuring point, the user can start the positioning via a user interface of the measuring device, for example, by pressing a button and/or tapping an operation field on a touch display, and the drive unit is then automatically started by the controller in such a way that the measuring device moves to the next measuring point and is positioned there. A user is thus able to position the measuring device particularly conveniently for acquiring magnetic field strength data. The user may cancel the automatic positioning at any time, for example, if there is a hazardous situation.

In one advantageous development of the measuring device according to the disclosure, it can be provided that the controller may comprise at least one of the following components:
a display unit,
a rechargeable energy storage element,
a data interface, which may be configured to exchange data with a mobile PC.

The rechargeable energy storage element facilitates wireless acquisition of the magnetic field strength, so that the user is also able to position the measuring device easily and safely without having to take a length of cable into account. Additionally, hazardous situations, which can arise due to the presence of a cable, can also thus be avoided advantageously. The rechargeable energy storage element may comprise a battery, particularly a rechargeable electrochemical energy store. Alternatively, or additionally, other rechargeable energy storage elements deemed useful by the person skilled in the art are also always possible, for example, capacitors.

The display unit may comprise a monitor and/or a display and/or a touch display. The display unit may be directly connected to the controller and/or the evaluation unit, so that the individual measured values and/or a magnetic field strength map can be displayed for the user immediately after the measurement and/or acquisition of the magnetic field strength.

The mobile PC can comprise a laptop or a tablet, etc. Furthermore, the mobile PC can comprise a display and/or a touch display. The mobile PC can be connected via the data interface directly to the controller for displaying the measured values, wherein no separate display unit is required for the controller in such a case. The mobile PC may be positioned directly on the measuring device, which has a receiving area for this purpose for receiving and/or arranging the mobile PC. In addition to the measured values being displayed for the user, the data can also be saved as a result on the mobile PC for a backup and/or further processing.

In one advantageous development of the measuring device according to the disclosure, it can be provided that the measuring device may comprise a housing, which may be configured to receive the controller, wherein the housing has a height in a measurement state and/or in a measurement arrangement of the measuring device that is greater than a length and/or width of the housing and wherein the housing is arranged so that it can be folded into the platform. A protected arrangement of the controller can be achieved by means of the housing.

In the measurement state and/or in the measurement arrangement of the measuring device, the height of the housing may also be greater than a length and greater than a width of the housing. In the measurement state and/or in the measurement arrangement of the measuring device, a surface of the housing facing upward can be used to hold a user interface of the controller or a mobile PC, which can be connected to the controller via a data interface. As a result, the user interface is located in a position that is easily accessible and easily visible for a user in the measurement state and/or in the measurement arrangement of the measuring device.

In the measurement arrangement and/or in the measurement state of the measuring device, the housing sits on the platform. In a storage arrangement and/or in a storage state of the measuring device, by contrast, the housing, together with the controller, is in a folded-in state on the platform, so that the housing is arranged horizontally on the platform. The housing may include a folding unit for this purpose, which enables the user to fold in the housing easily from the measurement arrangement and/or the measurement state to the storage arrangement and/or the storage state. The folding unit can also thereby comprise a fixing element and/or locking element, wherein the housing can be fixed by means of the fixing element and/or locking element to the platform, particularly fixed removably to the platform, both when vertical in the measurement arrangement and/or in the measurement state and when horizontal in the storage arrangement and/or in the storage state. The platform may be designed in such a way here that in the storage arrangement and/or in the storage state of the measuring device, the horizontal housing is resting almost completely on the platform, so that a protected arrangement of the housing and thus the controller is also provided in the storage arrangement and/or in the storage state of the measuring device.

In one advantageous development of the measuring device according to the disclosure, it can be provided that the measuring device may include a handle unit. The user is able to operate the measuring device easily by means of the handle unit, in particular is able to position it easily. In particular, a user can push or pull the measuring device to a measuring point by means of the handle unit.

Furthermore, the disclosure is based on a method for providing location-dependent magnetic field strength data for an environment of a magnetic resonance device, wherein the magnetic field strength data is acquired by means of the measuring device described above. The method may comprise:
positioning the measuring device at a measuring point, wherein sensor data from a position detection unit is used to position the measuring device,
acquiring magnetic field strength data by means of two or more magnetic field sensors of the measuring device, wherein the acquisition of magnetic field strength data may comprise acquiring a magnetic field strength at different height positions at the measuring point,
determining the location-dependent magnetic field strength data by means of a controller of the measuring device, and
providing the location-dependent magnetic field strength data.

The measuring device can thereby be positioned manually at the measuring point by a user, who positions the measuring device on a floor area in such a way, particularly by pushing or pulling, that the magnetic field sensors have the position of the measuring point in terms of the floor area. Alternatively, the measuring device can be positioned at the measuring point at least partially automatically by means of the controller and a travel unit of the measuring device, wherein the controller controls the travel unit accordingly, particularly a drive unit of the travel unit and individual wheels of the travel unit. The user and/or the controller can thereby access sensor data from the position detection unit. The sensor data is provided by a route sensor and/or a direction sensor and/or a distance sensor of the position detection unit and is displayed for the user on an output unit of the measuring device.

The two or more magnetic field sensors are arranged on a sensor rod of the measuring device, which extends vertically in a measurement arrangement and/or a measurement state. The two or more magnetic field sensors are thereby arranged spaced apart on the sensor rod. The two or more magnetic field sensors have a same position as the sensor rod and/or the measuring point with respect to the floor surface. However, the two or more magnetic field sensors differ in their vertical position along the sensor rod, so that the two or more magnetic field sensors differ in their height positions. These height positions and/or vertical positions of the individual magnetic field sensors are stored in the controller, particularly a memory unit of the controller, so that the entirety of the location information for an acquired value of a magnetic field strength is available to the controller.

The controller may evaluate the values acquired by the individual magnetic field sensors, along with the sensor data provided by the position detection unit, particularly the sensor data from the route sensor and/or the sensor data from the direction sensor and/or the sensor data from the distance sensor. Moreover, the controller may consider the height positions and/or vertical positions of the individual magnetic field sensors when evaluating the individual magnetic field sensors. Location-dependent magnetic field strength data is thereby determined and provided by the controller. The controller can thereby also determine and/or provide a magnetic field strength map of the environment of the magnetic resonance device. The controller may include an evaluation unit for this purpose.

The method according to the disclosure has the advantage that, in combination with multiple sensors, particularly magnetic field sensors and sensors of the position detection unit, location-dependent magnetic field strength data and/or also a magnetic field strength map can be provided particularly quickly. Additionally, a magnetic field strength can be acquired simultaneously at multiple height positions, which correspond in particular to arrangement points and/or fixing points on the sensor rod, at a measuring point along the perimeter of the transport container. This facilitates easy and quick acquisition of a magnetic field strength in an environment of a magnetic resonance device for a user, as the measuring points no longer need to be measured individually one after the other. This can reduce the time involved in installing and/or providing a mobile magnetic resonance device at a place of use, thereby increasing the cost-effectiveness of a mobile magnetic resonance device.

The advantages of the method according to the disclosure for providing location-dependent magnetic field strength data for an environment of a magnetic resonance device essentially correspond to the advantages of the measuring device according to the disclosure, which are explained in detail above. The features, advantages or alternative embodiments mentioned here may also be transferred to the other aspects of the disclosure and vice versa.

In one advantageous development of the method according to the disclosure, it can be provided that coordinates of the measuring point are determined with respect to a reference position. The reference position can thereby comprise a position of a previous measuring point and/or a position of a corner of a transport container, in which the magnetic resonance device is arranged, and/or a position of an opening, particularly a door, of the transport container and/or other positions in the environment of the magnetic resonance device deemed useful by the person skilled in the art. A change in position to a previous position and/or the reference position may be detected by means of the position detection unit, particularly the route sensor and/or the direction sensor and/or the distance sensor. At the beginning of magnetic field strength data acquisition, particularly for the first measuring point and/or a first measuring position, a position of a corner of the transport container or a position of an opening, particularly a door, of the transport container may be used as a reference position. For the second and the further measuring points, a position of the previous measuring point and/or the previous measuring position can also be used as a reference position. Each of the measuring points and/or each measuring position can thereby have a defined point and/or a defined position on a perimeter of the transport container.

For example, each of the four outer walls of the transport container can have its own reference position. A user can thereby select a reference position as the starting point for the acquisition and the measuring device is then positioned there, particularly manually by user or also at least partially automatically by means of the controller and the travel unit of the measuring device. Furthermore, the user may inform the controller, for example, via a user interface of the measuring device, that this is the starting point and/or the reference position for acquiring the magnetic field strength on this outer wall of the transport container. Alternatively, the controller can also suggest a starting point and/or a reference position to the user at the beginning of magnetic field strength data acquisition on an outer wall of the transport container.

This enables easy allocation of the acquired magnetic field strength data to location information in the environment encompassing the magnetic resonance device, particularly on the outer walls of the transport container, so that location-dependent magnetic field strength data can be determined and provided by the controller particularly easily and reliably.

In one advantageous development of the method according to the disclosure, it can be provided that a sensor rod of the measuring device has a minimal distance to a reference surface for acquiring the magnetic field strength data. The reference surface may comprise a wall surface, particularly an outer surface, of a container wall of the transport container, in which the magnetic resonance device is arranged. The minimal distance from the sensor rod to the wall surface of the transport container may be equal to 0 mm, so that the sensor rod directly abuts the wall surface of the transport container. It can thus be ensured that the sensor rod has no tilt and that all measured values acquired by the magnetic field sensors arranged on the sensor rod have the same location coordinates on the horizontal plane.

In one advantageous development of the method according to the disclosure, it can be provided that magnetic field strength data is acquired at different measuring points, wherein the different measuring points are evenly spaced apart around the perimeter of a space encompassing the magnetic resonance device. The space encompassing the magnetic resonance device may comprise a transport container, in which the magnetic resonance device is arranged and/or positioned. “Evenly spaced apart” is intended to mean that two adjacent measuring points along the perimeter of the space encompassing the magnetic resonance device always have an equal distance between them. The distance between two adjacent measuring points may not exceed 20 cm. The distance between two adjacent measuring points may comprise 15 cm and particularly advantageously 10 cm. The measuring points can also comprise an even net of measuring points on the wall surface, if the spacing of the measuring points along the sensor rod, particularly the spacing of the positions of the individual magnetic field sensors, is the same as a spacing of the measuring points around the perimeter of the space encompassing the magnetic resonance device. This allows for particularly precise detection of a critical value of the magnetic field strength being exceeded, particularly a magnetic field strength of 5 gauss. This also facilitates cordoning off a critical area and thus minimizing a risk to people in the environment of the magnetic resonance device.

In one advantageous development of the method according to the disclosure, it can be provided that the provided location-dependent magnetic field strength data is output by means of a user interface of the measuring device. The location-dependent magnetic field strength data can thus be communicated directly to a user.

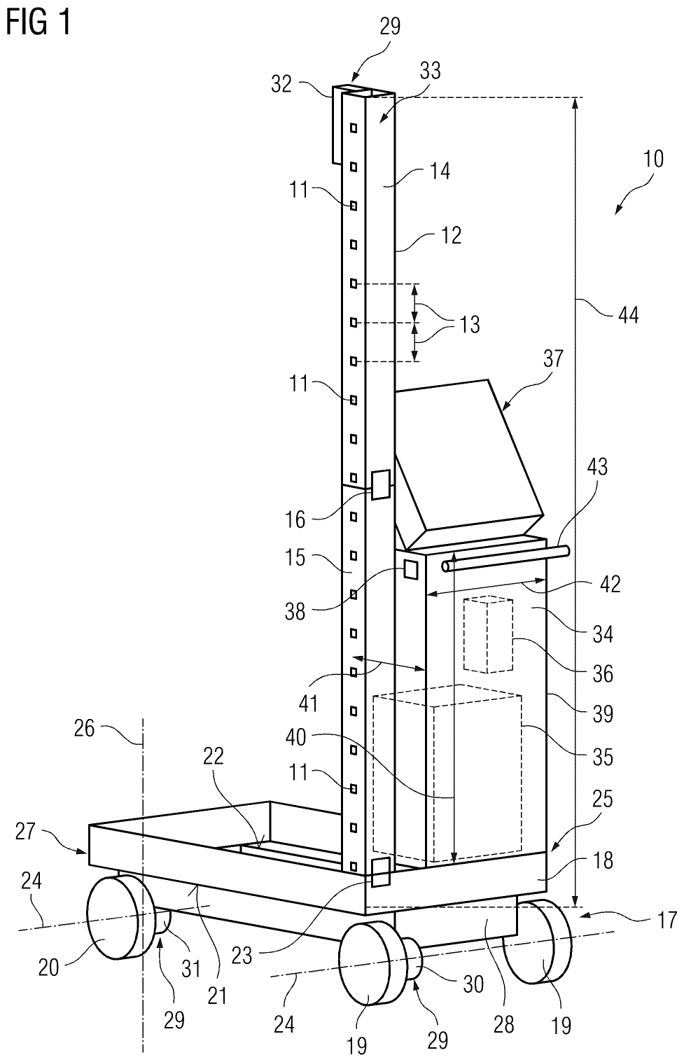

FIG. 1 shows a measuring device 10 for acquiring a magnetic field strength in an environment of a magnetic resonance device 50. The measuring device 10 may comprise here two or more magnetic field sensors 11, which are designed to acquire the magnetic field strength. In the present exemplary embodiment, the measuring device 10 may comprise 20 magnetic field sensors 11. In an alternative embodiment of the measuring device 10, this can also have more than 20 magnetic field sensors 11 or fewer than 20 magnetic field sensors 11.

Moreover, the measuring device 10 may include a sensor rod 12, on which the individual magnetic field sensors 11 are arranged distributed. In particular, two adjacent magnetic field sensors 11 are always a defined equal distance 13 apart. In the present exemplary embodiment, the distance 13 between two adjacent magnetic field sensors 11 is 10 cm. In an alternative embodiment of the measuring device 10, the distance 13 between two adjacent magnetic field sensors 11 can also comprise 15 cm or 20 cm, and so on, in each case. In the present exemplary embodiment, the sensor rod 12 is 2.0 m long. In an alternative embodiment of the measuring device 10, the sensor rod 12 can also be longer than 2.0 m or also shorter than 2.0 m.

The sensor rod 12 may include two sensor rod elements 14, 15 in the present exemplary embodiment. The two sensor rod elements 14, 15 are connected to each other via a first folding unit 16 of the sensor rod 12. The folding unit 16 may include a hinge element not shown in more detail and a locking element not shown in more detail. The hinge element may be configured to fold the first sensor rod element 14 in or out again with respect to the second sensor rod element 15. The locking element may be configured to fix and/or lock the first sensor rod element 14, particularly to fix and/or lock it removably and/or reversibly, in a measurement arrangement and/or in a measurement state, particularly in a folded-out position, with respect to the second sensor rod element 15. Furthermore, the locking element is also designed to fix and/or lock the first sensor rod element 14, particularly to fix and/or lock it removably and/or reversibly, in a folded-in position, particularly in a storage arrangement and/or a storage state, with respect to the second sensor rod element 15.

The measuring device 10 may include a travel unit 17. The travel unit 17 may comprise a platform 18 and wheels 19, 20. The wheels 19, 20 are arranged on an underside 21 of the platform 18. The platform 18 may include a rectangular basic form in the present exemplary embodiment, wherein the sensor rod 12 is arranged on an upper side 22 of the platform 18, particularly facing away from the wheels 19, 20. The sensor rod 12 thereby may include a longitudinal extension 44, which is aligned orthogonally to a surface of the platform 18 in the measurement arrangement and/or in the measurement state of the sensor rod 12.

A second folding unit 23 of the sensor rod 12 is arranged between the platform 18 and the second sensor rod element 15. The second folding unit 23 may include a hinge element not shown in more detail and a locking element not shown in more detail. The hinge element of the second folding unit 23 may be configured to fold the second sensor rod element 15 in or out again with respect to the platform 18. The locking element of the second folding unit 23 may be configured to fix and/or lock the second sensor rod element 15, particularly to fix and/or lock it removably and/or reversibly, in the measurement arrangement and/or in the measurement state, particularly in a folded-out position, with respect to the platform 18. Furthermore, the locking element of the second folding unit 23 is also designed to fix and/or lock the second sensor rod element 15, particularly to fix and/or lock it removably and/or reversibly, in a folded-in position, particularly in the storage arrangement and/or the storage state, with respect to the platform 18.

The travel unit 17 may include at least two wheels 19, 20. In the present exemplary embodiment, the travel unit 17 may include four wheels 19, 20. Two of the wheels 19 have just one rotational axis 24 in each case. The wheels 19 rotate about this rotational axis 24 to move the measuring device 10 or rather to roll the wheels 19. The rotational axis 24 is thereby perpendicular to an idealized circular area, wherein the circular area is encompassed by an outer surface of the wheel 19, which may comprise a rolling surface of the wheel 19. The wheels 19 with just one rotational axis 24 are arranged in a rear area 25 of the measuring device 10 in the present exemplary embodiment.

Additionally, the wheels 20 of the travel unit 17 have two rotational axes 24, 26 in each case. The design of the first rotational axis 24 of the two wheels 20 is analogous to that of the rotational axis 24 of the two wheels 19 with just one rotational axis 24. The second rotational axis 26 is aligned perpendicular to the first rotational axis 24 and also perpendicular to the platform 18. The wheels 20 rotate about this rotational axis 26 to change direction when the measuring device 20 moves, in particular when it runs. In the present exemplary embodiment, the two wheels 20 with the two rotational axes 24, 26 comprise the front wheels of the travel unit 17 and are arranged in a front area 27 of the measuring device 10.

Moreover, the travel unit 17 may include a drive unit 28 with a motor in the present exemplary embodiment. The drive unit 28, particularly the motor, is used to produce a driving moment to move the measuring device 10. The driving moment produced by the motor is transferred from the drive unit to at least two of the wheels 19, 20 of the travel unit 17.

In an alternative embodiment of the disclosure, the measuring device 10 can also be embodied without a drive unit 28. In such a case, a user is required to provide thrust power to move the measuring device 10.

The measuring device 10 may include a position detection unit (detector) 29, which may be configured to detect a change in position of the measuring device 10. The position detection unit 29 may include a route sensor 30 and/or a position sensor for this purpose. The route sensor 30 and/or position sensor may comprise an angle sensor and/or rotary encoder, which are arranged on a wheel 19 of the travel unit 17 and which determine a traveled distance and/or a change in route on the basis of a rotation and/or change in angle of the wheel 19. The route sensor 30 and/or position sensor are arranged coaxially to the first rotational axis 24 on a wheel 19 of the travel unit 17 for this purpose. In the present exemplary embodiment, the route sensor 30 and/or position sensor are arranged on a rear wheel of the drive unit 17.

The position detection unit (detector) 29 also may comprise a direction sensor 31, which may be configured to detect a change in direction. The direction sensor 31 is arranged on a wheel 20 with two rotational axes 24, 26 of the travel unit 17. In the present exemplary embodiment, the direction sensor 29 may comprise an angle sensor and/or rotary encoder, which detect a change in direction based on a rotation and/or change in angle of the wheel 20 about the second rotational axis 26. The direction sensor 31 is arranged coaxially here to the second rotational axis 26 on one of the wheels 20 of the travel unit 17.

The position detection unit 29 may include a distance sensor 32, which may be configured to determine a distance to a reference surface 57. The reference surface 57 may comprise a wall surface 58, for example, an outer surface, of the transport container 51. The distance sensor 32 can comprise one or more time-of-flight (TOF) sensors. Alternatively, or additionally, the distance sensor 32 can also comprise one or more 2D cameras. Alternatively, or additionally, the distance sensor 32 can also comprise one or more 3D cameras. Alternatively, or additionally, the distance sensor 32 can also comprise one or more light detection and ranging (LIDAR) sensors. The distance sensor 32 is arranged on the sensor rod 12. The distance sensor 32 is arranged here on an end area 33 of the sensor rod 12 facing away from the platform 18.

The measuring device 10 may include a controller 34, which may be configured to evaluate the sensor data from the magnetic field sensors 11 and from the sensors of the position detection unit 29, such as from the route sensor 30, the direction sensor 31, and the distance sensor 32. The controller 34 may include an evaluation unit (processor, processing circuitry) 35 for this purpose with suitable software for evaluating the sensor data. The controller 34 (e.g., the evaluation unit 35) may be configured to determine and provide location-dependent magnetic field strength data. In an exemplary embodiment, the controller 24 includes processing circuitry that is configured to perform one or more functions and/or operations of the controller 24. Additionally, or alternatively, one or more components of the controller 24 may include processing circuitry that is configured to perform one or more respective functions and/or operations of the component(s).

The controller 34 may be configured to control the drive unit 28 for automatic positioning of the measuring device 10. The controller 34 thereby uses the sensor data from the route sensor 30, the direction sensor 31, and the distance sensor 32 of the position detection unit for correct positioning of the measuring device 10 in a measuring position.

Furthermore, the controller 34 may include a rechargeable energy storage element 36, such as a battery. In the present exemplary embodiment, the controller 34 may also comprise a user interface 37, particularly a display unit with a touch display, so that a user can communicate with the controller 34 while positioning the measuring device 10. Additionally, the location-dependent magnetic field strength data determined by the controller 34, particularly the evaluation unit 35, is output to the user via the display unit.

In an exemplary embodiment of the disclosure, the controller 34 may omit a separate user interface 37 or display unit. In this example, the controller 34 may include a data interface 38 configured to exchange data with a mobile PC, for example, a laptop and/or a tablet.

The measuring device 10 may include a housing 39, which may be configured to receive the controller 34. This housing 39 may include an upper side, on which the user interface 37 with the touch display is arranged. If the controller 34 does not comprise a separate user interface 37, a mobile PC can also be positioned on this upper side.

In the measurement state and/or in the measurement arrangement of the measuring device 10, the housing 39 may include a height 40, which is greater than a length 41 of the housing 39. Furthermore, in the measurement state and/or in the measurement arrangement of the measuring device 10, the height 40 of the housing 39 is also greater than a width 42 of the housing 39. As a result, the user interface 37 is located in a position that is easily accessible and easily visible for a user in the measurement state and/or in the measurement arrangement of the measuring device 10.

The housing 39 is also arranged so that it can be folded into the platform 18. In the measurement arrangement and/or in the measurement state of the measuring device 10, the housing 39 sits on the platform 18. In the storage arrangement and/or in the storage state of the measuring device 10, by contrast, the housing 39, together with the controller 34, is in a folded-in state on the platform 18, so that the housing 39 is arranged horizontally on the platform 18. For this purpose, the housing 39 may include a folding unit with a fixing element not shown in more detail, wherein the fixing element fixes the housing 39 to the platform 18, particularly fixes it removably, both when vertical in the measurement arrangement and/or in the measurement state and when horizontal in the storage arrangement and/or in the storage state. The platform 18 is designed in such a way that in the storage arrangement and/or in the storage state of the measuring device 10, the horizontal housing 39 is resting completely on the platform 18, so that the housing 39 and thus the controller 34 are also in a protected arrangement in the storage arrangement and/or in the storage state of the measuring device 10.

The measuring device 10 may include a handle unit 43, which is arranged on the housing 39 that receives the controller 34. The handle unit 43 enables a user to move the measuring device 10 manually, particularly by pushing. The handle unit 43 is arranged in the rear area 25 of the measuring device 10.

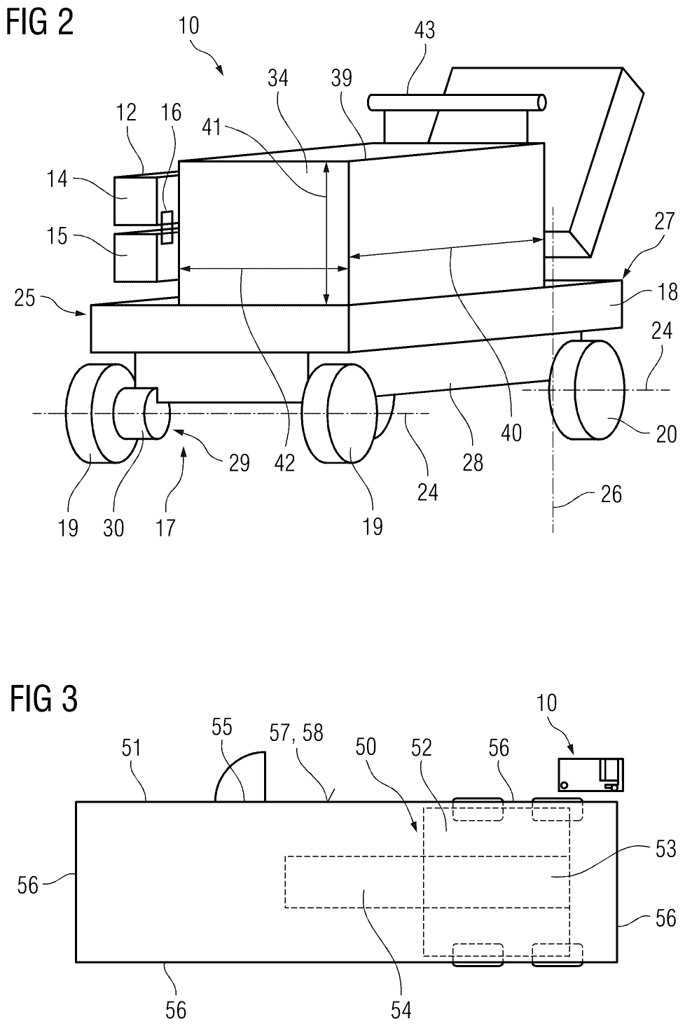

In FIG. 2, the measuring device 10 is shown in the storage arrangement and/or in the storage state. In this storage arrangement and/or in the storage state, both the housing 39, which receives the controller 34, and the folded sensor rod 12 are arranged horizontally on the platform 18.

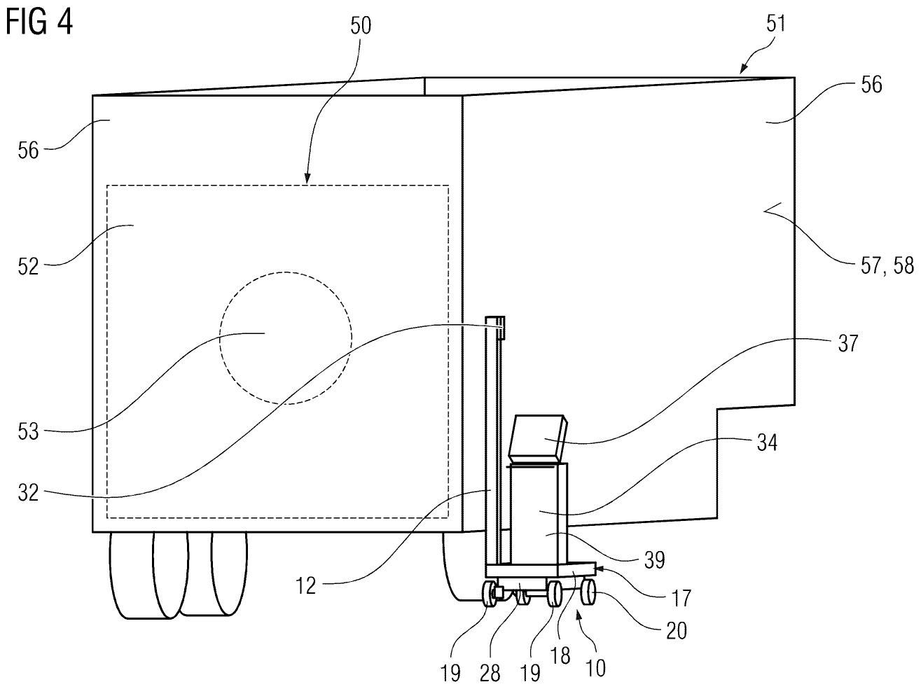

In FIGS. 3 and 4, the measuring device 10 is shown in an environment of a magnetic resonance device 50. The magnetic resonance device may comprise a mobile magnetic resonance device 50, which is arranged and/or positioned in a transport container 51. As the mobile magnetic resonance device 50 is located within the transport container 51, it is only shown with dashed lines in FIGS. 3 and 4. The mobile magnetic resonance device 50 within the transport container 51 is fully functional and operational for performing magnetic resonance examinations.

The magnetic resonance device 50 may comprise a magnet unit 52 with a base magnet, a gradient coil unit, and a radio-frequency antenna unit. The base magnet of the magnet unit 52 may be configured to generate a strong and in particular constant base magnetic field. The gradient coil unit of the magnet unit 52 may be configured to generate magnetic field gradients, which are used for spatial encoding during imaging. The radio-frequency antenna unit of the magnet unit 52 may be configured to stimulate a polarization, which occurs in the base magnetic field generated by the base magnet.

Furthermore, the magnetic resonance device 50 may include a patient receiving area 53 for receiving a patient for a magnetic resonance examination. The magnetic resonance device 50 may include a patient support device 54 with a patient table for positioning the patient, in particular an area of the patient to be examined, within the patient receiving area 53. The patient table is designed for positioning the patient, in particular the area of the patient to be examined, movably within the patient receiving area 53. In particular, the patient table is movably supported in the direction of a longitudinal extension of the patient receiving area 53 and/or in the z-direction.

The magnetic resonance device 50 described may of course comprise further components, which magnetic resonance devices 50 generally have. A general functioning of a magnetic resonance device 50 will also be known to the person skilled in the art, so that a detailed description of the further components may be dispensed with.

The transport container 51 may include an entry 55, for example, a door, and four side walls 56. The magnetic field strength for each of the four walls 56 must be acquired by means of the measuring device 10 before the magnetic resonance device 50 is commissioned at a location. As is apparent in FIGS. 3 and 4, the measuring device 10 is positioned for this purpose on the outer walls of the transport container 51 and acquires the magnetic field strength.

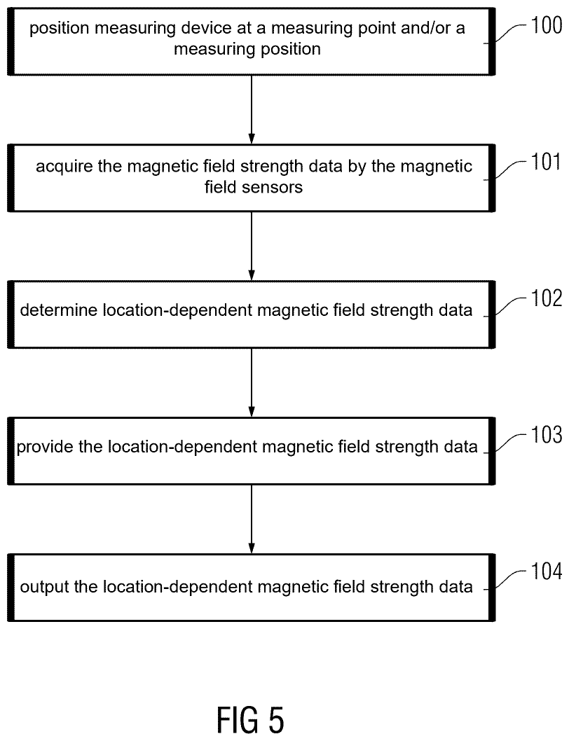

FIG. 5 shows a method for providing location-dependent magnetic field strength data for an environment of a magnetic resonance device 50. The magnetic field strength data is thereby acquired by means of the measuring device 10 shown above. The method is controlled by the controller 34 of the measuring device 10, which may include appropriate software for this purpose.

In a first method step 100, the measuring device 10 is positioned at a measuring point and/or a measuring position, wherein sensor data from the position detection unit 29 is used to position the measuring device 10. If the measuring device 10 may comprise a drive unit 28, as in the present exemplary embodiment, the controller 34 uses the sensor data from the position detection unit 29, particularly the sensor data from the route sensor 30, the sensor data from the direction sensor 31, and the sensor data from the distance sensor 32, to position the measuring device 10 precisely at the measuring point and/or a measuring position. The measuring point may comprise a point and/or position on a perimeter of a base area of the transport container 51, at which the measuring device 10 is to be positioned for acquiring the magnetic field strength data. The measuring point and/or the measuring position can thereby also comprise a position of the sensor rod, at which this is to be positioned for acquiring the magnetic field strength data.

If, by contrast, the measuring device 10 does not comprise a drive unit 28, the user may position the measuring device 10 manually at the measuring point at the measuring position. The necessary position data is provided here to the user via the user interface 37 of the controller 34.

The measuring device 10 is thereby positioned with respect to a reference position, particularly in terms of determining coordinates of a measuring point. Such a reference position can comprise a position of the previous measuring point and/or a position of a corner of the transport container 51 and/or a position of an opening, particularly a door, of the transport container 51. For example, each of the four outer walls can have its own and/or separate reference position. A user can thereby select a reference position as the starting point for the acquisition and the measuring device 10 is then positioned there by the controller 34. Additionally, the user informs the controller 34, for example, via the user interface 37 of the measuring device 10, that this is the starting point and/or the reference position for acquiring the magnetic field strength on this outer wall of the transport container 51. Moreover, in this method step 100, the controller 34 can also suggest a starting point and/or a reference position to the user at the beginning of magnetic field strength data acquisition.

When positioning the measuring device 10, the measuring device 10 is positioned on the wall surface 58 in such a way that the measuring device 10, particularly the sensor rod 12, may include a minimal distance to the wall surface 58, particularly the outer surface of the container wall. The minimal distance from the sensor rod 12 to the wall surface 58 may be equal to 0 mm, so that the sensor rod 12 directly abuts the wall surface 58.

In a further, second method step 101, the magnetic field strength data is acquired by means of the magnetic field sensors 11. Due to the arrangement of the magnetic field sensors 11 on the sensor rod 12, with the magnetic field sensors 11 being arranged evenly spaced apart in the longitudinal direction of the sensor rod 12, in this second method step 101, magnetic field strength data is acquired simultaneously at multiple points, corresponding to the number of magnetic field sensors 11, wherein the magnetic field strength data from the magnetic field sensors 11 is acquired at different height positions. Moreover, due to the arrangement of the magnetic field sensors 11 on the sensor rod 12, all magnetic field strength data acquired at a measuring point and/or measuring position of the measuring device 10 may include the same coordinates on the horizontal plane. In the vertical direction, by contrast, the coordinates of the acquired magnetic field strength data differ and have different height positions.

In a further, third method step 102, location-dependent magnetic field strength data is determined by means of the controller 34, particularly the evaluation unit 35. The evaluation unit 35 thereby evaluates the values acquired by the individual magnetic field sensors 11, along with the sensor data from the route sensor 30, the sensor data from the direction sensor 31, and the sensor data from the distance sensor 32, and determines location-dependent magnetic field strength data. The controller 34, particularly the evaluation unit 35, can thereby also determine and/or create a magnetic field strength map of the environment of the magnetic resonance device 50.

In a further, fourth method step 103, the location-dependent magnetic field strength data is provided by the evaluation unit 35. In particular, the location-dependent magnetic field strength data is provided to the user interface 37 for output. In a fifth method step 104, the location-dependent magnetic field strength data is output to a user by the user interface 37.

The method, particularly the method steps 100 to 104, is repeated until magnetic field strength data, particularly location-dependent magnetic field strength data, is available for all measuring points. Magnetic field strength data is thereby acquired at different measuring points, wherein the different measuring points are evenly spaced around the perimeter of the transport container 51. The distance between two measuring points may not exceed 20 cm. The distance between two adjacent measuring points may comprise 15 cm and particularly advantageously 10 cm.

Although the disclosure has been illustrated and described in detail with the exemplary embodiments, the disclosure is not restricted by the examples disclosed and other variations may be derived therefrom by a person skilled in the art without departing from the protective scope of the disclosure.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A measuring device for acquiring a magnetic field strength in an environment of a magnetic resonance device, the device comprising:
a sensor rod; and
two or more magnetic field sensors arranged and distributed on the sensor rod.

2. The measuring device as claimed in claim 1, wherein the two or more magnetic field sensors are arranged on the sensor rod such that two adjacent magnetic field sensors equally spaced apart.

3. The measuring device as claimed in claim 1, further comprising a travel unit including a platform, wherein the sensor rod is arranged on the platform.

4. The measuring device as claimed in claim 3, wherein the sensor rod has a longitudinal extension aligned orthogonally to a surface of the platform.

5. The measuring device as claimed in claim 3, wherein the travel unit comprises at least two wheels.

6. The measuring device as claimed in claim 5, wherein at least one of the at least two wheels comprises a single rotational axis and at least another of the at least two wheels comprises two rotational axes.

7. The measuring device as claimed in claim 3, wherein the travel unit comprises a drive unit.

8. The measuring device as claimed in claim 1, wherein the sensor rod comprises at least one folding unit.

9. The measuring device as claimed in claim 1, further comprising a position detector configured to detect a change in position of the measuring device, the position detector comprising a route sensor.

10. The measuring device as claimed in claim 9, wherein the route sensor is arranged coaxially to a rotational axis on a wheel of a travel unit.

11. The measuring device as claimed in claim 9, wherein the position detector comprises a direction sensor arranged on a wheel of a travel unit with two rotational axes.

12. The measuring device as claimed in claim 9, wherein the position detector comprises a distance sensor configured to determine a distance to a reference surface.

13. The measuring device as claimed in claim 12, wherein the distance sensor is arranged on the sensor rod on an end area of the sensor rod facing away from a platform of a travel unit.

14. The measuring device as claimed in claim 1, further comprising a controller configured to evaluate sensor data from the two or more magnetic field sensors and/or one or more sensors of a position detector.

15. The measuring device as claimed in claim 14, wherein the controller is configured to control a drive unit to automatically position the measuring device.

16. The measuring device as claimed in claim 14, wherein the controller comprises:
a display unit;
a rechargeable energy storage element; and/or
a data interface configured to exchange data with an external computing device.

17. The measuring device as claimed in claim 14, further comprising a housing configured to receive the controller, the housing including a height in a measurement state of the measuring device that is greater than a width and/or a length of the housing, wherein the housing is arranged such that the housing is foldable into a platform of a travel unit.

18. The measuring device as claimed in claim 1, further comprising a handle unit.

19. A method for providing location-dependent magnetic field strength data for an environment of a magnetic resonance device, comprising:
positioning a measuring device at a measuring point based on sensor data from a position detector of a measuring device;
acquiring, by the two or more magnetic field sensors of the measuring device, the magnetic field strength data, wherein the acquisition of the magnetic field strength data comprises acquiring a magnetic field strength at different height positions at the measuring point;
determining, by a controller of the measuring device, the location-dependent magnetic field strength data; and
providing the location-dependent magnetic field strength data as an electronic output signal.

20. The method as claimed in claim 19, further comprising determining coordinates of the measuring point based on a reference position.

21. The method as claimed in claim 20, wherein the reference position comprises a previous measuring point and/or a position of a corner of a transport container, in which the magnetic resonance device is located, and/or a position of an opening of the transport container.

22. The method as claimed in claim 19, wherein a sensor rod of the measuring device comprises a minimal distance to a reference surface for acquiring the magnetic field strength data.

23. The method as claimed in claim 19, wherein the magnetic field strength data is acquired at different measuring points, wherein the different measuring points are evenly spaced apart around a perimeter of a space encompassing the magnetic resonance device.

24. The method as claimed in claim 19, wherein the provided location-dependent magnetic field strength data is output by a user interface of the measuring device.
